(19) United States
(12) Patent Application Publication
(10) Pub. No.: US 2022/0246518 A1
(43) Pub. Date: Aug. 4, 2022

(54) SEMICONDUCTOR DEVICE

(71) Applicant: Kioxia Corporation, Tokyo (JP)

(72) Inventor: Keisuke UCHIDA, Yokkaichi (JP)

(73) Assignee: Kioxia Corporation, Tokyo (JP)

(21) Appl. No.: 17/393,740

(22) Filed: Aug. 4, 2021

(30) Foreign Application Priority Data
Feb. 2, 2021 (JP) 2021-015333

(51) Int. Cl. H01L 23/522; H01L 23/532; H01L 27/11556; H01L 27/11582; H01L 21/768

(52) U.S. Cl. CPC H01L 23/5226; H01L 23/53257; H01L 23/5329; H01L 21/76877; H01L 27/11582; H01L 21/76802; H01L 27/11556

(57) ABSTRACT

A semiconductor device according to an embodiment includes a plurality of first conductive layers stacked apart from each other and including a plate-like shape extending in a first direction intersecting a stacking direction of the plurality of first conductive layers, one of both side surfaces extending in the first direction having larger surface roughness than the other; a plurality of channel bodies configured to penetrate the plurality of first conductive layers in the stacking direction, the plurality of channel bodies including semiconductors; and a memory film extending in the stacking direction between each of the plurality of channel bodies and the plurality of first conductive layers and including a charge accumulation film.

### CROSS-REFERENCE TO RELATED APPLICATION

This application is based upon and claims the benefit of priority from Japanese Patent Application No. 2021-015333 filed on Feb. 2, 2021 in Japan, the entire contents of which are incorporated herein by reference.

### FIELD

Embodiments described herein relate generally to a semiconductor device and a method for fabricating the semiconductor device.

### BACKGROUND

In the development of semiconductor devices, particularly, semiconductor storage devices, miniaturization of memory cells has been advanced to achieve a large capacity, a low cost, and the like. For example, the development of a three-dimensional NAND type flash memory device in which memory cells are three-dimensionally disposed has been advanced. In the three-dimensional NAND type flash memory device, a NAND string in which memory cells are connected in a direction (so-called stacking direction) perpendicular to a surfaces of a word line layer is formed in the word line layer stacked with a dielectric layer therebetween. As a result, high integration is achieved as compared with a case where the memory cells are two-dimensionally disposed. In the three-dimensional NAND type flash memory device, there is a problem that voids may be formed in a conductive layer when the conductive layer to be a word line is embedded in a space sandwiched by dielectric layers. The formation of the void may deteriorate the resistance of the word line. As a result, a yield may be deteriorated. Therefore, improvement of embeddability of the conductive layer to be the word line is desired.

### BRIEF DESCRIPTION OF THE DRAWINGS

FIG. 1 is a cross-sectional view illustrating an example of a configuration of a semiconductor device in a first embodiment;

FIG. 2 is a top view illustrating an example of a configuration of a conductive layer of each layer in the first embodiment;

FIG. 3 is an enlarged top view of an example of one word line in the first embodiment;

FIG. 4 is an enlarged top view of another example of one word line in the first embodiment;

FIG. 5 is a flowchart illustrating main steps of a method for fabricating the semiconductor device in the first embodiment;

FIG. 6 is a cross-sectional view illustrating a part of the steps of the method for fabricating the semiconductor device in the first embodiment;

FIG. 7 is a cross-sectional view illustrating another part of the steps of the method for fabricating the semiconductor device in the first embodiment;

FIG. 8 is a cross-sectional view illustrating an example of a configuration of a memory cell region in the first embodiment;

FIG. 9 is a cross-sectional view illustrating another part of the steps of the method for fabricating the semiconductor device in the first embodiment;

FIG. 10 is a cross-sectional view illustrating another part of the steps of the method for fabricating the semiconductor device in the first embodiment;

FIG. 11 is a cross-sectional view illustrating another part of the steps of the method for fabricating the semiconductor device in the first embodiment;

FIG. 12 is a cross-sectional view illustrating another part of the steps of the method for fabricating the semiconductor device in the first embodiment;

FIG. 13 is a cross-sectional view illustrating another part of the steps of the method for fabricating the semiconductor device in the first embodiment;

FIG. 14 is a cross-sectional view illustrating another part of the steps of the method for fabricating the semiconductor device in the first embodiment;

FIG. 15 is a cross-sectional view illustrating another part of the steps of the method for fabricating the semiconductor device in the first embodiment;

FIGS. 16A to 16D are diagrams for describing a cross section of a stacked film in a comparative example of the first embodiment;

FIGS. 17A to 17C are diagrams for describing a cross section of a stacked film in the first embodiment;

FIG. 18 is a diagram for describing an example of a cross section of a stacked film in which a division layer of a selection gate is disposed in a comparative example of the first embodiment; and

FIGS. 19A and 19B are diagrams for describing an example of a cross section of a stacked film in which a division layer of a selection gate is disposed in the first embodiment.

### DETAILED DESCRIPTION

A semiconductor device according to an embodiment includes a plurality of first conductive layers, a plurality of channel bodies, and a memory film. The plurality of first conductive layers is stacked apart from each other and includes a plate-like shape extending in a first direction intersecting a stacking direction of the plurality of first conductive layers, one of both side surfaces of the plurality of first conductive layers extending in the first direction having larger surface roughness than the other of both side surfaces. The plurality of channel bodies is configured to penetrate the plurality of first conductive layers in the stacking direction, the plurality of channel bodies including semiconductors. The memory film is extending in the stacking direction between each of the plurality of channel bodies and the plurality of first conductive layers and includes a charge accumulation film.

In the following embodiments, a semiconductor device capable of reducing voids generated in a conductive layer to be a word line of a three-dimensional NAND type flash memory device will be described.

Further, in the following embodiments, the three-dimensional NAND type flash memory device will be described as an example of a semiconductor device. Hereinafter, description will be given using the drawings. Note that, in each drawing, x, y, and z directions are orthogonal to each other, and the z direction may be described as an upward direction or an upper layer direction and an opposite direction thereof may be described as a downward direction or a lower layer direction.

### First Embodiment

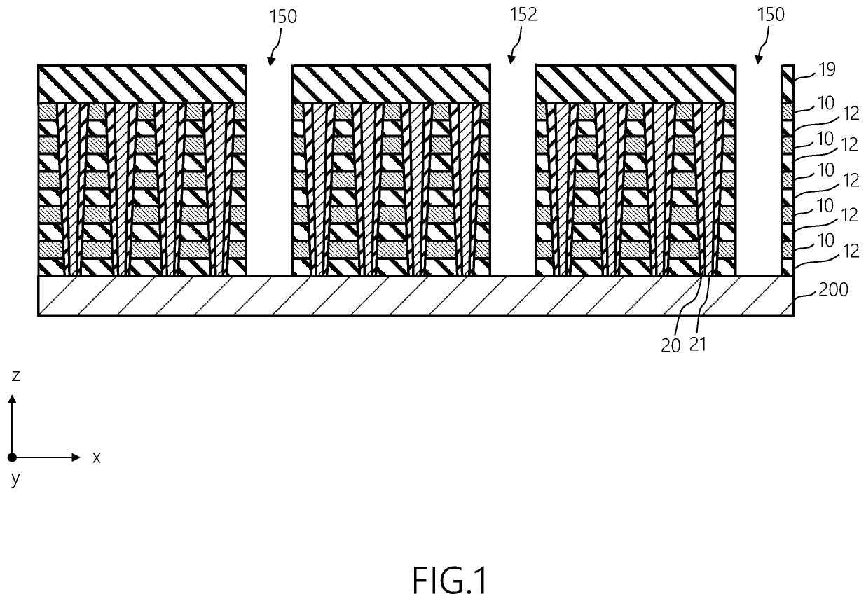

FIG. 1 is a cross-sectional view illustrating an example of a configuration of a semiconductor device in a first embodiment. In FIG. 1, in the semiconductor device according to the first embodiment, each layer of a plurality of conductive layers 10 stacked apart from each other to be word lines (WL) in the semiconductor storage device and each layer of a plurality of dielectric layers 12 insulating adjacent conductive layers 10 from each other are alternately stacked on a semiconductor substrate 200 (substrate). In the first embodiment, the plurality of dielectric layers 12 are alternately stacked with the plurality of conductive layers 10 and disposed in direct contact with adjacent conductive layers 10. Each dielectric layer 12 and the adjacent conductive layer 10 are disposed without a block dielectric film such as aluminum oxide described later, for example, therebetween. In addition, each conductive layer 10 and the adjacent dielectric layer 12 are disposed without a barrier metal film such as titanium nitride (TiN), for example, therebetween.

The conductive layer 10 of each layer is a plate-like layer extending in a first direction (y direction) intersecting a stacking direction (z direction) of the plurality of conductive layers 10 so as to straddle a word line contact region and a memory cell region. In the example of FIG. 1, a case where each conductive layer 10 extends in a plate-like shape toward the back side of a plane of paper is illustrated. In addition, in the example of FIG. 1, the memory cell region is illustrated. Hereinafter, illustration of the word line contact region is omitted in the respective drawings. In the example of FIG. 1, the dielectric layer 12 is first disposed on the semiconductor substrate 200, and the uppermost conductive layer 10 is covered with a dielectric film 19. The conductive layer 10 of each layer is separated from the adjacent conductive layer 10 by openings 150 and 152 (grooves) in a direction (x direction) orthogonal to the first direction that is the longitudinal direction of the plate-like conductive layer 10. In the example of FIG. 1, a state in which the openings 150 and 152 are formed is illustrated, and conductors (not illustrated) having insulating spacers on sidewalls are disposed in the openings 150 and 152 to configure the semiconductor storage device. Alternatively, the openings 150 and 152 may be embedded with insulators.

In addition, a columnar channel body 21 penetrating a stacked body of the plurality of conductive layers 10 and the plurality of dielectric layers 12 in the stacking direction is disposed in the memory cell region. As a material of the channel body 21, a semiconductor material is used. Then, in the memory cell region, a memory film 20 including a charge accumulation film is disposed between each conductive layer 10 and the channel body 21. The memory film 20 is disposed in a tubular shape penetrating the stacked body of the plurality of conductive layers 10 and the plurality of dielectric layers 12 in the stacking direction so as to surround the entire side surface of the channel body 21. By a combination of the conductive layer 10 to be the word line, the memory film 20, and the channel body 21 surrounded by the memory film 20, one memory cell is configured. By a plurality of memory cells obtained by connecting memory cells in the conductive layer 10 of each layer which the channel body 21 and the memory film 20 penetrate, one NAND string is configured. In addition, a plurality of channel bodies 21 and a memory film 20 surrounding each channel body 21 are disposed in the conductive layer 10 of one layer. In the example of FIG. 1, a case where four memory cells including the channel body 21 and the memory film 20 are arranged in a width direction of the word line is illustrated.

One end of each channel body 21 is connected to another bit line contact and bit line (not illustrated) above the stacked body, for example. The other end of each channel body 21 is connected to a common source line (not illustrated) below the stacked body, for example. In the columnar channel body 21, a tubular structure having a bottom portion may be formed using a semiconductor material and a core portion using an insulating material may be disposed in an inner portion thereof.

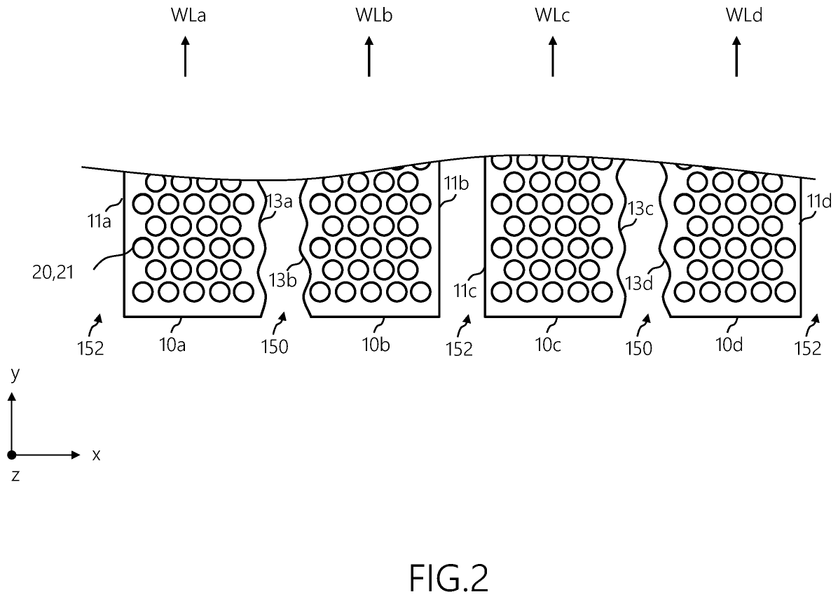

FIG. 2 is a top view illustrating an example of a configuration of the conductive layer of each layer in the first embodiment. In FIG. 2, a plurality of conductive layers 10a, 10b, 10c, and 10d of the respective layers extend in a plate-like shape toward an upper side (y direction) of a plane of paper. In each of the plurality of conductive layers 10a, 10b, 10c, and 10d of the respective layers, a plurality of memory cells including the plurality of channel bodies 21 and memory films 20 are disposed. In the example of FIG. 2, a case where the plurality of channel bodies 21 and memory films 20 (memory cells) are disposed in a staggered lattice in each conductive layer 10 is illustrated.

In the first embodiment, the plurality of plate-like conductive layers 10 stacked apart from each other and extending in the first direction (y direction) intersecting the stacking direction (z direction) are formed such that one of both side surfaces extending in the first direction (y direction) has surface roughness larger than that of the other. In the example of FIG. 2, a case is illustrated in which one side surface 13 of the plurality of conductive layers 10a, 10b, 10c, and 10d arranged in the x direction of each layer is formed so as to have surface roughness larger than that of the other side surface 11. In the plurality of conductive layers 10a, 10b, 10c, and 10d arranged in the x direction of each layer, the adjacent conductive layers 10 are insulated from each other, and the side surfaces 13 having the large surface roughness or the side surfaces 11 having the small surface roughness are arranged so as to face each other. For example, in the conductive layer 10a to be a word line WLa and the conductive layer 10b to be a word line WLb, the side surfaces 13 (side surfaces 13a and 13b) having the large surface roughness face each other. In the next conductive layer 10b and the conductive layer 10c to be a word line WLc, the side surfaces 11 (side surfaces 11b and 11c) having the small surface roughness face each other. Further, in the next conductive layer 10c and the conductive layer 10d to be a word line WLd, the side surfaces 13 (side surfaces 13c and 13d) having the large surface roughness face each other. Thereafter, the case where the facing surfaces are the side surfaces 11 and the case where the facing surfaces are the side surfaces 13 are alternately repeated.

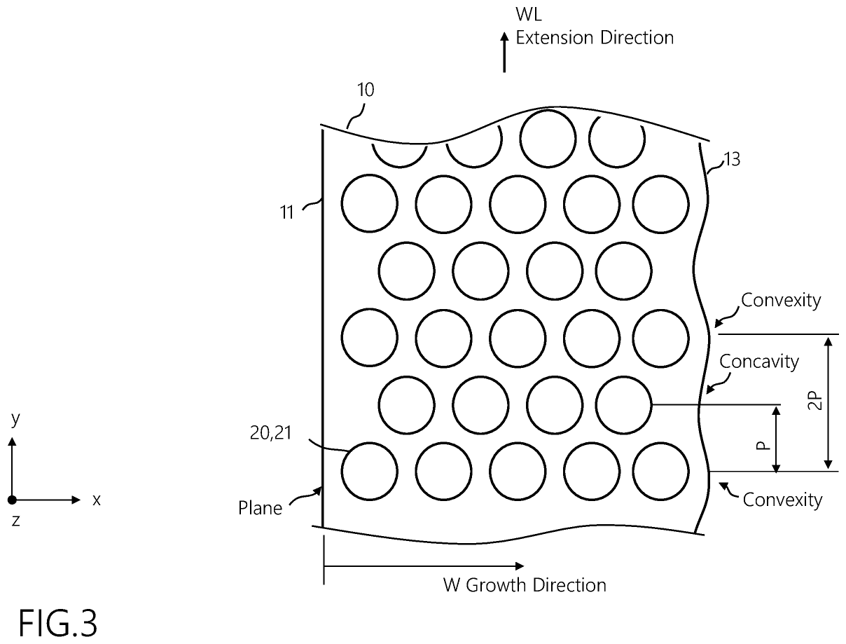

FIG. 3 is an enlarged top view of an example of one word line in the first embodiment. In FIG. 3, one side surface 13 of each of the conductive layers 10 in which the plurality of memory films 20 (and channel bodies 21) are disposed in a staggered lattice repeats concavity and convexity in a period (2P) that is twice an arrangement pitch P of the plurality of memory films 20 (and the channel bodies 21) along the first direction (y direction) in which the conductive layers 10 extend. Note that a method for disposing the plurality of memory films 20 (and channel bodies 21) is not limited to the staggered lattice.

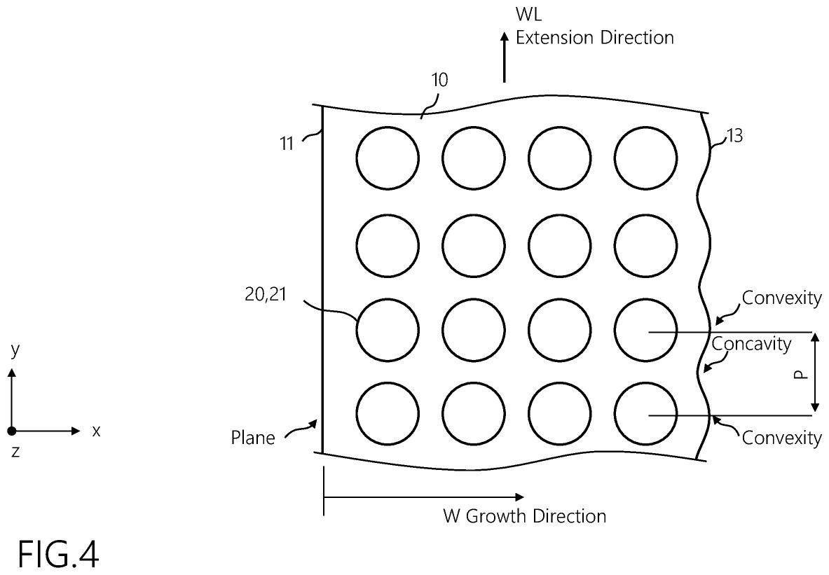

FIG. 4 is an enlarged top view of another example of one word line in the first embodiment. In FIG. 4, a case where a plurality of memory films 20 (and channel bodies 21) are disposed in a square lattice in each conductive layer 10 is illustrated. As described above, the plurality of memory films 20 (and channel bodies 21) may be disposed in a square lattice. One side surface 13 of each of the conductive layers 10 in which the plurality of memory films 20 (and channel bodies 21) are disposed in a square lattice repeats concavity and convexity in a period (1P) similar to the arrangement pitch P of the plurality of memory films 20 (and the channel bodies 21) along the first direction (y direction) in which the conductive layers 10 extend.

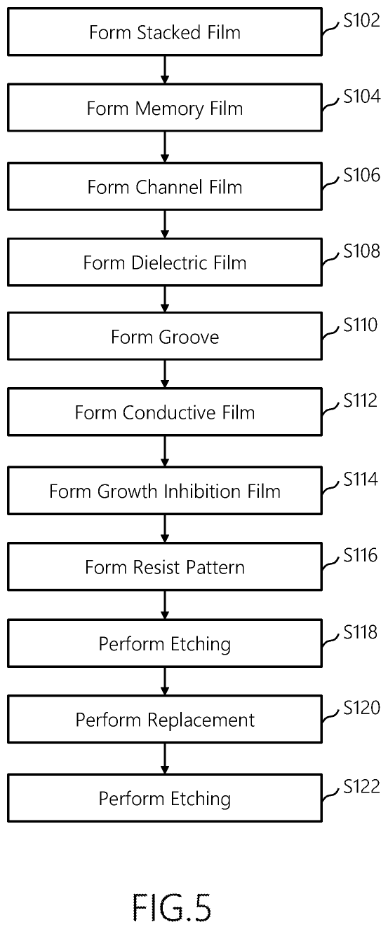

FIG. 5 is a flowchart illustrating main steps of a method for fabricating the semiconductor device in the first embodiment. In FIG. 5, in the method for fabricating the semiconductor device in the first embodiment, a series of steps including a stacked film formation step (S102), a memory film formation step (S104), a channel film formation step (S106), a dielectric film formation step (S108), a groove formation step (S110), a conductive film formation step (S112), a growth inhibition film formation step (S114), a resist pattern formation step (S116), an etching step (S118), a replacement step (S120), and an etching step (S122) is executed.

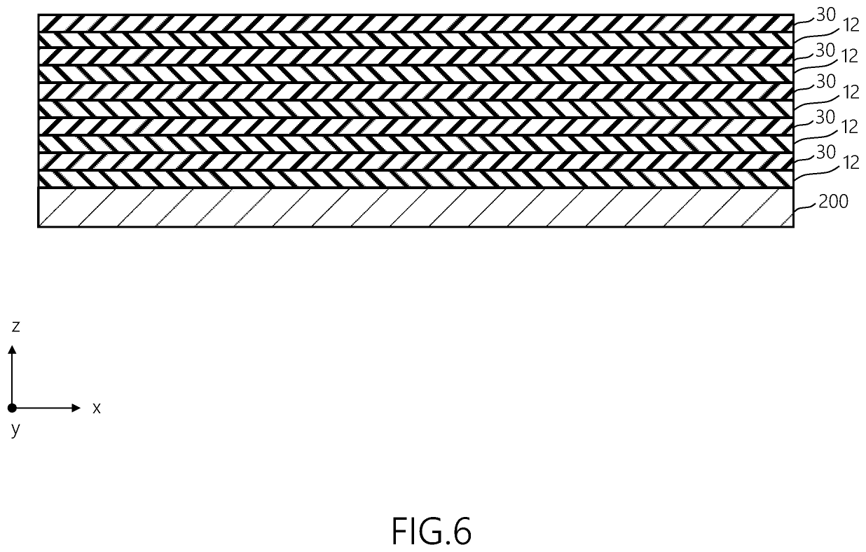

FIG. 6 is a cross-sectional view illustrating a part of the steps of the method for fabricating the semiconductor device in the first embodiment. In FIG. 6, the stacked film formation step (S102) of FIG. 5 is illustrated. The subsequent steps will be described later.

In FIG. 6, as the stacked film formation step (S102), first, the dielectric layers 12 and sacrificial film layers 30 are alternately stacked on the semiconductor substrate 200 by using an atomic layer vapor phase growth (atomic layer deposition: ALD or atomic layer chemical vapor deposition: ALCVD) method or a chemical vapor deposition (CVD) method, for example. In the example of FIG. 6, a case where the dielectric layer 12 is formed on the semiconductor substrate 200, and then the sacrificial film layers 30 and the dielectric layers 12 are alternately stacked is illustrated. By this step, a stacked film (stacked body) in which the sacrificial film layer 30 which is each layer of the plurality of sacrificial film layers 30 and the dielectric layer 12 which is each layer of the plurality of dielectric layers 12 are alternately stacked is formed. As a sacrificial film used for the sacrificial film layer 30, for example, a silicon nitride film (SiN film) is preferably used. As a dielectric film used for the dielectric layer 12, for example, a silicon oxide film (SiO₂ film) is preferably used. As the semiconductor substrate 200, for example, a silicon wafer having a diameter of 300 mm is used. On or in the semiconductor substrate in which the sacrificial film layers 30 and the dielectric layers 12 are alternately stacked, other dielectric films, wires, contacts, and/or semiconductor elements such as transistors, which are not illustrated in the drawings, may be formed.

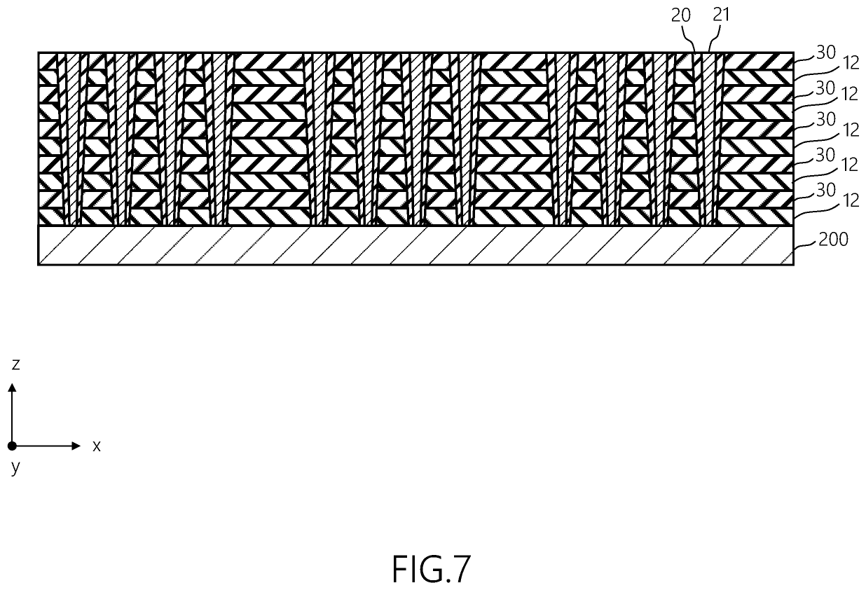

FIG. 7 is a cross-sectional view illustrating another part of the steps of the method for fabricating the semiconductor device in the first embodiment. In FIG. 7, the memory film formation step (S104) and the channel film formation step (S106) in FIG. 5 are illustrated. The subsequent steps will be described later.

In FIG. 7, as the memory film formation step (S104), first, a plurality of openings (memory holes), which have a circular cross section, for example, penetrating the stacked film from the uppermost layer of the stacked film, for example, the sacrificial film layer 30, are formed.

Specifically, in a state in which a resist film is formed on the sacrificial film layer 30 through a lithography step such as a resist coating step and an exposure step (not illustrated), the exposed sacrificial film layer 30, and the stacked film of the sacrificial film layer 30 and the dielectric layer 12 located below the exposed sacrificial film layer 30 are removed by an anisotropic etching method, so that the memory holes can be formed substantially perpendicularly to the surface of the sacrificial film layer 30. For example, the memory holes may be formed by a reactive ion etching (RIE) method. In the first embodiment, the stacked body is formed such that the sacrificial film layer 30 becomes an exposed surface, but the present disclosure is not limited thereto. The stacked body may be formed such that the dielectric layer 12 becomes the exposed surface.

Then, the memory film 20 is formed in each of the formed memory holes.

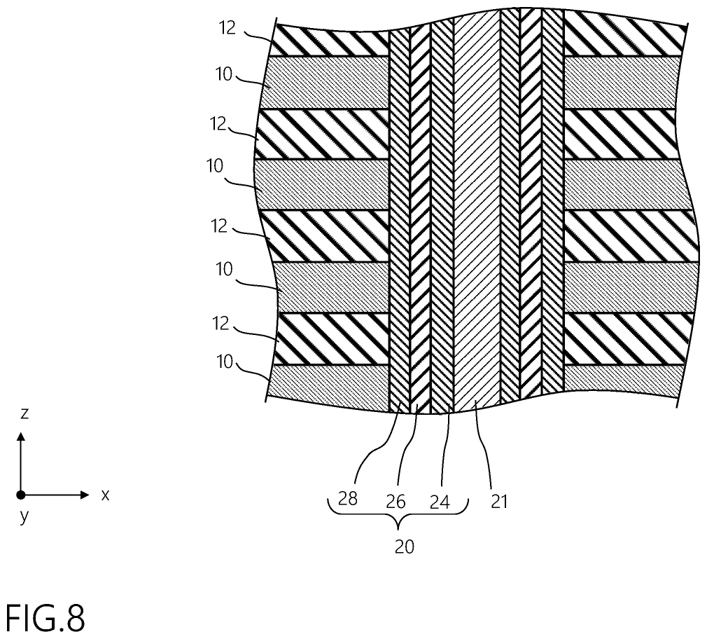

FIG. 8 is a cross-sectional view illustrating an example of a configuration of the memory cell region in the first embodiment. In FIG. 8, a state after the sacrificial film layer 30 is replaced with the conductive layer 10 is illustrated. The memory film 20 has a block dielectric film 28, a charge accumulation film 26, and a tunnel dielectric film 24. In other words, the memory film 20 has the block dielectric film 28 disposed between the charge accumulation film 26 and the plurality of conductive layers 10 so as to extend in the stacking direction. Hereinafter, internal steps will be specifically described.

As a block dielectric film formation step, the block dielectric film 28 is formed along a sidewall surface of each memory hole by using the ALD method, the ALCVD method, or the CVD method, for example. The block dielectric film 28 is a film that suppresses the flow of charges between the charge accumulation film 26 and the conductive layer 10. As a material of the block dielectric film 28, for example, aluminum oxide (Al₂O₃) or a SiO₂ film is preferably used. As a result, the block dielectric film 28 disposed in a tubular shape along the sidewall surface of the memory hole can be formed as a part of the memory film 20.

Next, as a charge accumulation film formation step, the charge accumulation film 26 is formed along the sidewall surface of the block dielectric film 28 in each memory hole by using the ALD method, the ALCVD method, or the CVD method, for example. The charge accumulation film 26 is a film including a material capable of accumulating charges. As the material of the charge accumulation film 26, for example, SiN is preferably used. As a result, the charge accumulation film 26 disposed in a tubular shape along the inner wall surface of the block dielectric film 28 can be formed as a part of the memory film 20.

Next, as a tunnel dielectric film formation step, the tunnel dielectric film 24 is formed along the sidewall surface of the charge accumulation film 26 in each memory hole by using the ALD method, the ALCVD method, or the CVD method, for example. The tunnel dielectric film 24 is a dielectric film for allowing a current to flow by applying a predetermined voltage, although it has an insulating property. As the material of the tunnel dielectric film 24, for example, SiO₂ is preferably used. As a result, the tunnel dielectric film 24 disposed in a tubular shape along the inner wall surface of the charge accumulation film 26 can be formed as a part of the memory film 20.

Next, as the channel film formation step (S106), a channel film to be the channel body 21 is formed in a columnar shape along the inner wall surface of the tunnel dielectric film 24 in each memory hole by using the ALD method, the ALCVD method, or the CVD method, for example. As a material of the channel film, a semiconductor material is used. For example, it is preferable to use silicon (Si) doped with impurities. As a result, the channel body 21 can be formed in a columnar shape along the entire circumference of the inner wall surface of the tunnel dielectric film 24.

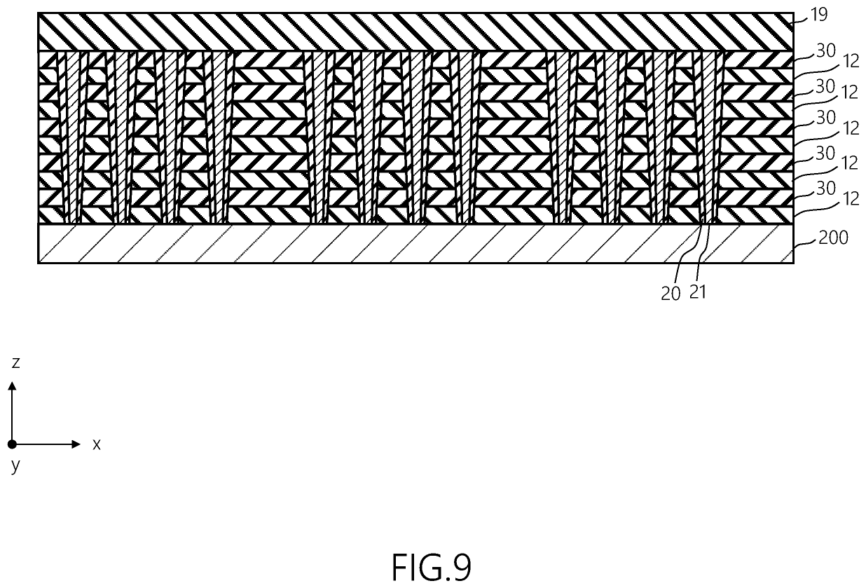

FIG. 9 is a cross-sectional view illustrating another part of the steps of the method for fabricating the semiconductor device in the first embodiment. In FIG. 9, the dielectric film formation step (S108) of FIG. 5 is illustrated. The subsequent steps will be described later.

In FIG. 9, as the dielectric film formation step (S108), the dielectric film 19 is formed on the stacked body in which the memory film 20 and the channel body 21 are formed by using the ALD method, the ALCVD method, or the CVD method, for example. As the material of the dielectric film 19, for example, SiC₂ is preferably used.

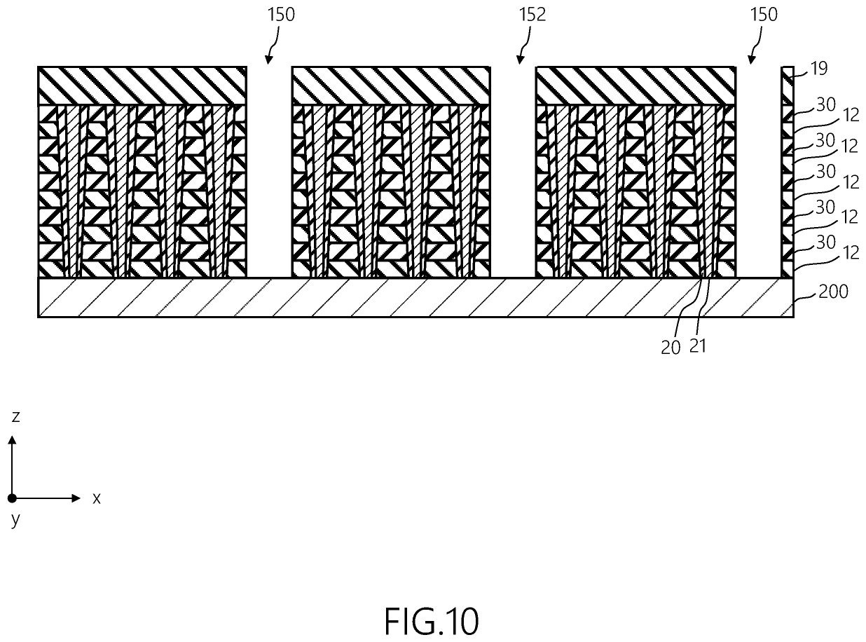

FIG. 10 is a cross-sectional view illustrating another part of the steps of the method for fabricating the semiconductor device in the first embodiment. In FIG. 10, the groove formation step (S110) of FIG. 5 is illustrated. The subsequent steps will be described later.

In FIG. 10, as the groove formation step (S110), a plurality of openings 150 and 152 (grooves) for separating word lines are formed in order to form a plurality of word lines in each layer. The plurality of openings 150 and 152 are grooves extending in parallel with the word lines in the first direction (y direction) in which the word lines extend. The width between the two openings 150 and 152 is the width of each word line in the direction (x direction) orthogonal to the first direction (y direction) in which the word line extends. Here, the opening 150 and the opening 152 are alternately and repeatedly formed. However, each of the openings 150 and 152 may be a groove having the same width.

Specifically, in a state in which a resist film is formed on the dielectric film 19 through a lithography step such as a resist coating step and an exposure step (not illustrated), the exposed dielectric film 19, and the stacked film of the sacrificial film layer 30 and the dielectric layer 12 located below the dielectric film 19 is removed by an anisotropic etching method, so that opening grooves can be formed substantially perpendicularly to the surface of the dielectric film 19. For example, the plurality of openings 150 and 152 may be formed by a reactive ion etching method.

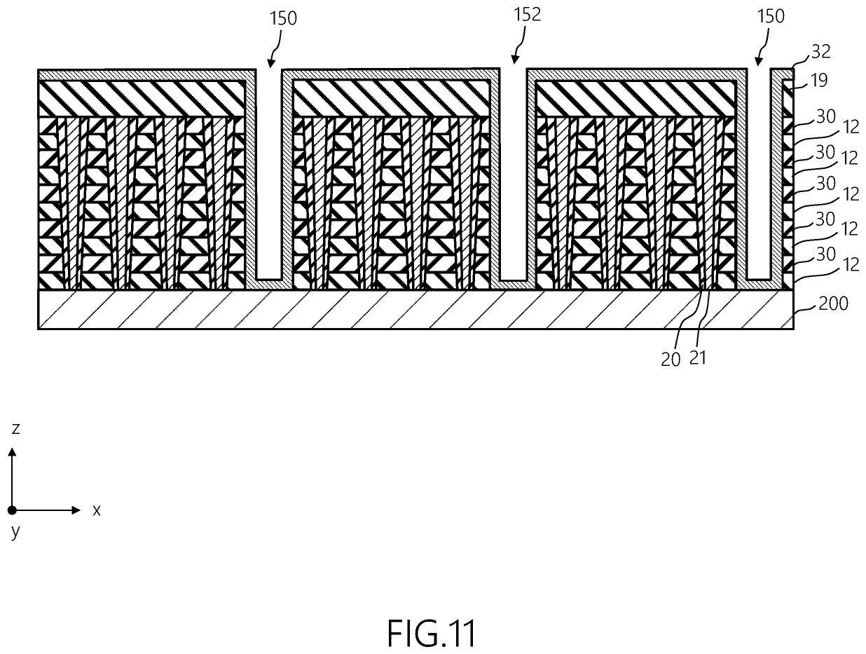

FIG. 11 is a cross-sectional view illustrating another part of the steps of the method for fabricating the semiconductor device in the first embodiment. In FIG. 11, the conductive film formation step (S112) of FIG. 5 is illustrated. The subsequent steps will be described later.

In FIG. 11, as the conductive film formation step (S112), the conductive film 32 using the same material as the material used as the word line is formed on at least the sidewalls of the plurality of openings 150 and 152. As the material of the conductive film 32, for example, tungsten (W) is used. Specifically, for example, the conductive films 32 are formed on the dielectric film 19 and on the sidewalls and the bottom surfaces of the plurality of openings 150 and 152 by using a CVD method.

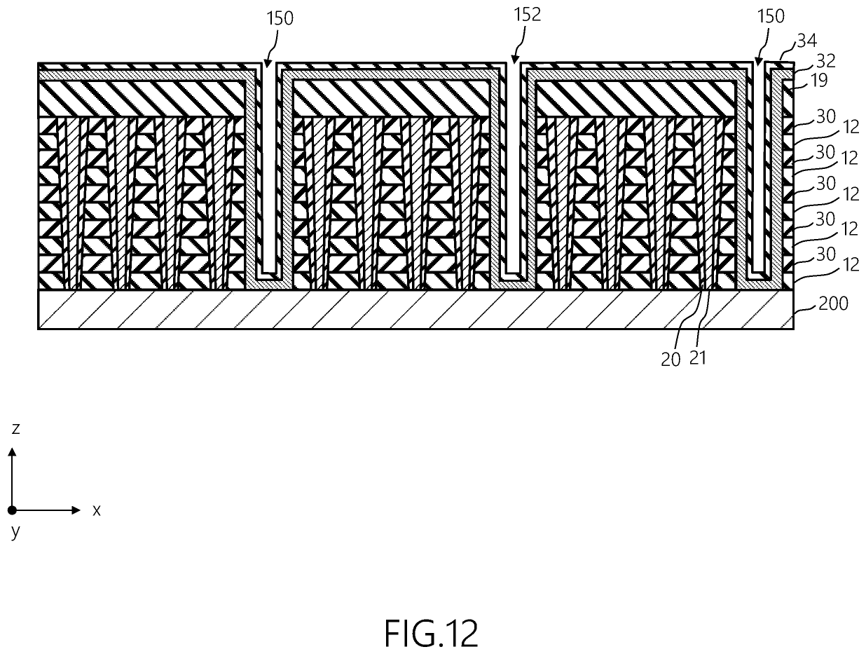

FIG. 12 is a cross-sectional view illustrating another part of the steps of the method for fabricating the semiconductor device in the first embodiment. In FIG. 12, the growth inhibition film formation step (S114) of FIG. 5 is illustrated. The subsequent steps will be described later.

In FIG. 12, as the growth inhibition film formation step (S114), a growth inhibition film 34 that inhibits the growth of the conductive film 32 during the replacement step (S120) described later is formed on at least the sidewalls of the plurality of openings 150 and 152. As the material of the growth inhibition film 34, for example, SiO₂ is used. Specifically, for example, the growth inhibition film 34 is formed on the conductive film 32 including the sidewalls and the bottom surfaces of the plurality of openings 150 and 152 using the CVD method. Since the growth inhibition film 34 is removed later, it is preferable to adjust the film thickness so as not to completely embed the plurality of openings 150 and 152 from the viewpoint of shortening a removal time.

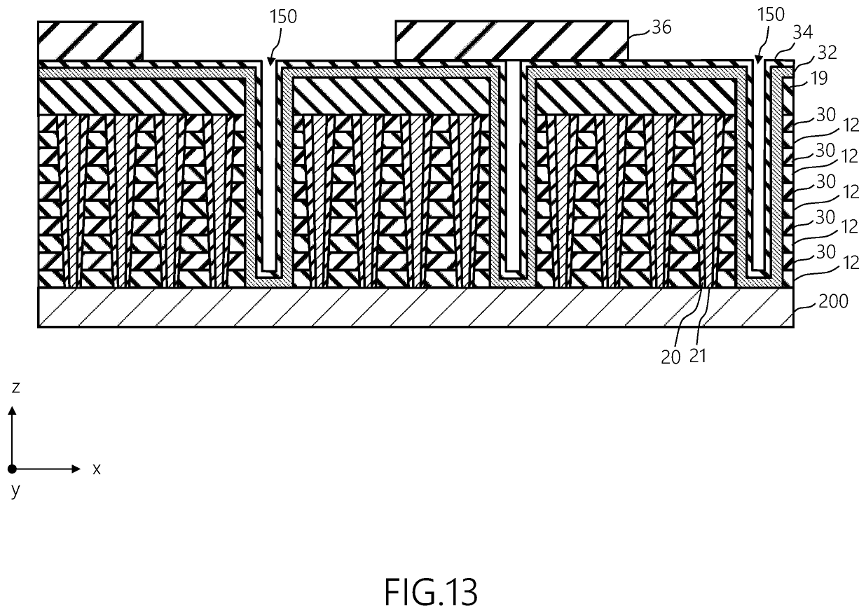

FIG. 13 is a cross-sectional view illustrating another part of the steps of the method for fabricating the semiconductor device in the first embodiment. In FIG. 13, the resist pattern formation step (S116) of FIG. 5 is illustrated. The subsequent steps will be described later.

In FIG. 13, as the resist pattern formation step (S116), first, a resist film is formed on the growth inhibition film 34 so as to cover the upper side of the plurality of openings 150 and 152. Then, of the openings 150 and 152 being alternately arranged, a resist pattern 36 is formed such that the opening 150 is exposed while the upper side of the opening 152 is covered. In other words, the resist pattern 36 is formed so as to cover every other groove among the plurality of grooves (openings 150 and 152) continuously arranged in the x direction.

Specifically, the resist pattern 36 is formed by a lithography step of exposing a 1:1 line-and-space pattern to the resist film such that the opening 152 is at a substantially center position of a line pattern and the opening 150 is at a substantially center position of a space pattern, after a resist coating step (not illustrated).

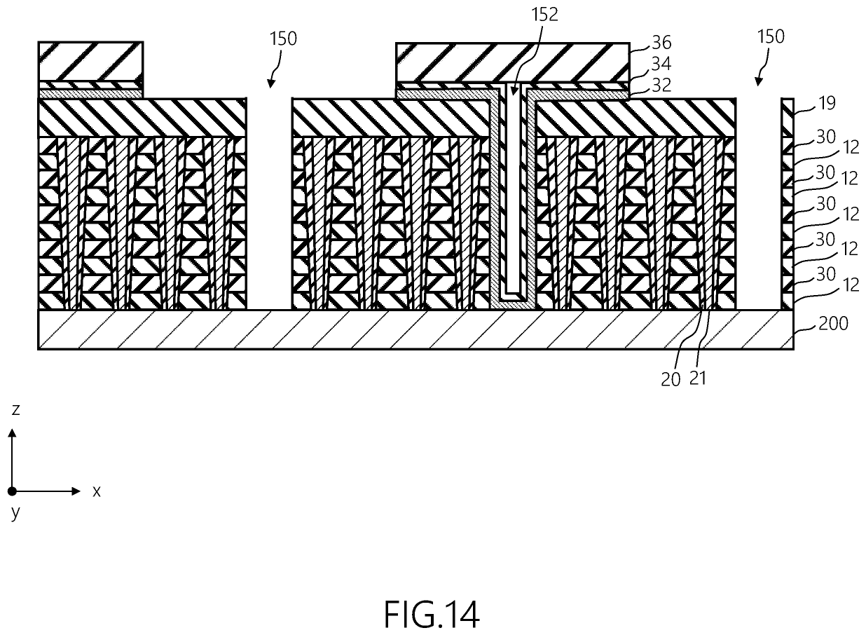

FIG. 14 is a cross-sectional view illustrating another part of the steps of the method for fabricating the semiconductor device in the first embodiment. In FIG. 14, the etching step (S118) of FIG. 5 is illustrated. The subsequent steps will be described later.

In FIG. 14, as the etching step (S118), the exposed growth inhibition film 34 is removed by etching using the resist pattern 36 as a mask, and thereafter, the exposed conductive film 32 is removed by etching. As a result, as illustrated in FIG. 14, the sacrificial film layers 30 of the respective stacked layers can be exposed to the sidewall in the opening 150 of the adjacent openings 150 and 152, and the wall of the conductive film 32 can be left on the sidewall in the adjacent opening 152 and the conductive film 32 can be covered with the growth inhibition film 34. The remaining resist pattern 36 may be removed by ashing after the conductive film 32 is removed by etching. Alternatively, the resist pattern 36 may be left. Alternatively, the resist pattern 36 may be removed together when the conductive film 32 is etched.

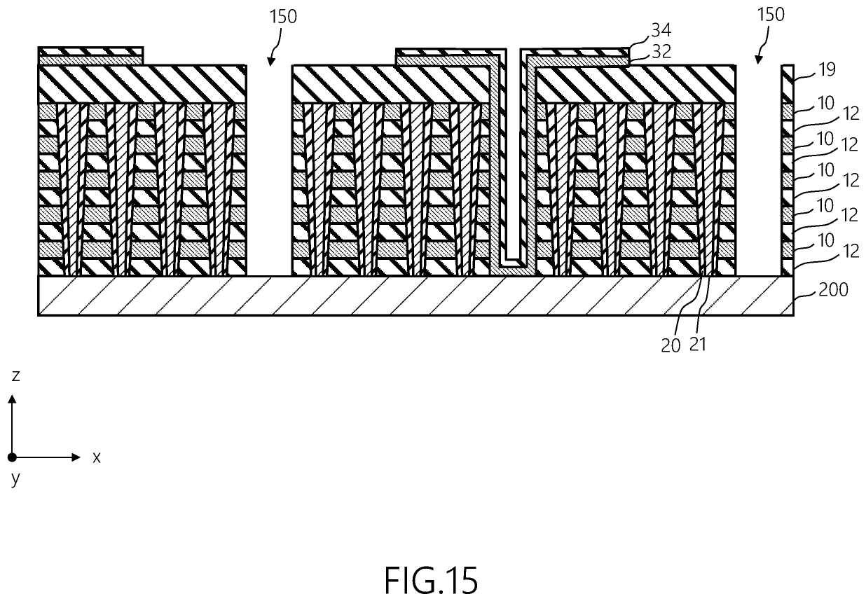

FIG. 15 is a cross-sectional view illustrating another part of the steps of the method for fabricating the semiconductor device in the first embodiment. In FIG. 15, the replacement step (S120) of FIG. 5 is illustrated. The subsequent steps will be described later.

In FIG. 15, as the replacement step (S120), the stacked sacrificial film layer 30 is replaced with the conductive layer 10. Specifically, the following operation is performed. First, the sacrificial film layer 30 of each layer is removed by etching through the opening 150 to be a groove for replacement using a wet etching method (for example, hot phosphoric acid treatment). As a result, a space is formed between the dielectric layers 12 of the respective layers. In the memory cell region, the memory film 20 and the channel body 21 extending in the stacking direction intersecting the dielectric layer 12 of each layer serve as support members (pillars), and can support the dielectric layer 12 of each layer so as not to collapse.

Then, a conductive material to be a word line is embedded in the space between the dielectric layers 12 of the respective layers through the opening 150 to be the groove for replacement using the CVD method to form the conductive layer 10. In the first embodiment, the conductive layer 10 and the dielectric layer 12 adjacent to each other are brought into contact with each other without disposing a barrier metal film between the conductive layer 10 and the dielectric layer 12. Further, as the conductive material of the conductive layer 10, W is preferably used.

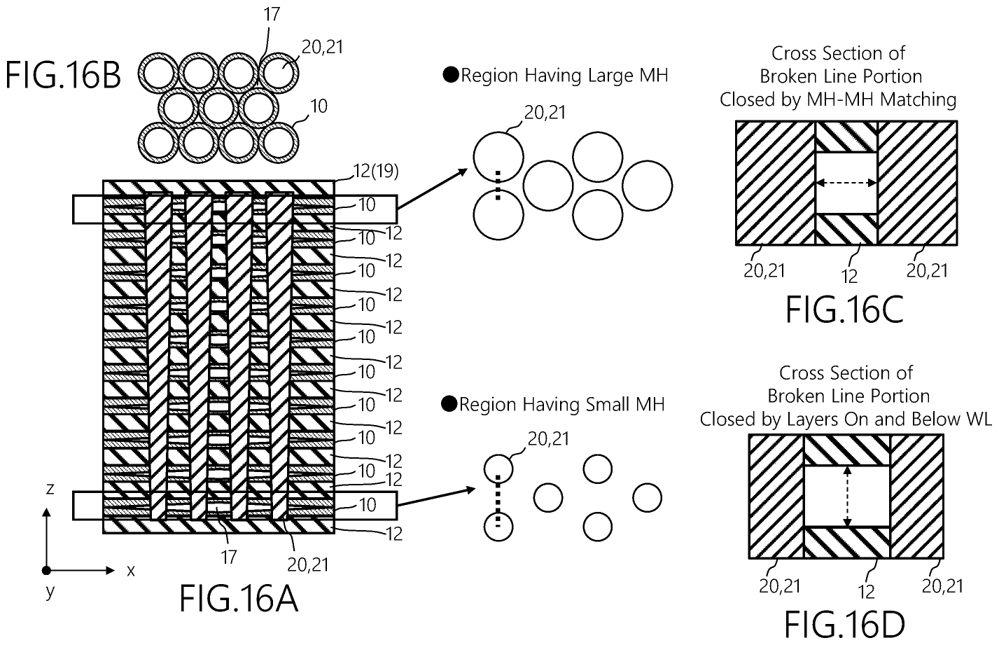

FIGS. 16A to 16D are diagrams for describing a cross section of a stacked film in a comparative example of the first embodiment. FIG. 16A illustrates an example of a cross section of a stacked layer in which a conductive material is embedded through both the openings 150 and 152 as grooves for replacement. In the comparative example, the conductive layer 10 is formed by growing a W film on the dielectric layer 12 from a state where the W film does not exist. Alternatively, the conductive layer 10 of the W film is formed by growing the W film on a barrier metal film (not illustrated) from a state where the W film does not exist. As a result, as illustrated in FIG. 16A, voids 17 may be formed in the conductive layer 10. For example, as illustrated in FIG. 16B, the voids 17 are easily formed in a region between the memory films 20.

Specifically, due to the processing characteristics of the memory holes, a columnar structure configured by the memory film 20 and the channel body 21 tends to be thick on the side of the upper layer and thin on the side of the lower layer. As a result, in a state where the sacrificial film layer 30 is removed, the distance between the memory films 20 is short on the side of the upper layer as illustrated in FIG. 16C. Therefore, the distance between the memory films 20 is shorter than the distance between the two adjacent dielectric layers 12. As a result, before the entire space is completely filled with the conductive material, the memory films 20 may be connected to each other with the conductive material, and the space may be closed with the voids left. As illustrated in FIG. 16D, the distance between the memory films 20 is long on the side of the lower layer. Therefore, the distance between the memory films 20 is longer than the distance between the two adjacent dielectric layers 12. As a result, before the entire space is completely filled with the conductive material, the two adjacent dielectric layers 12 may be connected with the conductive material, and the space may be closed with the voids left.

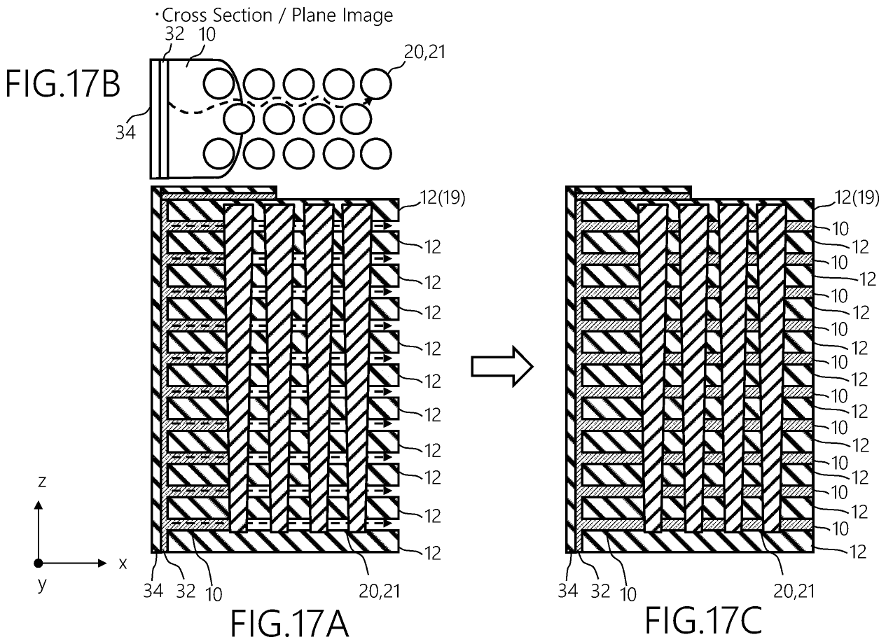

FIGS. 17A to 17C are diagrams for describing a cross section of a stacked film in the first embodiment. FIG. 17A illustrates an example of a cross section of a stacked layer in which a conductive material is embedded through the opening 150 as the groove for replacement in a state where the wall of the conductive film 32 is disposed on the sidewall of the opening 152 of the openings 150 and 152 alternately formed. FIG. 17B is a top view of one conductive layer surface illustrating how the conductive layer is grown. As illustrated in FIGS. 17A and 17B, in the first embodiment, the wall of the conductive film 32 is disposed at one of both ends in the width direction of the word line.

Here, in a case where the W film is grown on the dielectric layer 12 as in the comparative example, an incubation time becomes long due to poor film attachment. On the other hand, in the first embodiment, since the W film is grown on the conductive film 32 of the same W film, the incubation time can be shortened as compared with the case where the W film is grown on the dielectric layer 12 as in the comparative example. As a result, in the first embodiment, the W film to be the conductive layer 10 can be selectively grown in a direction from the conductive film 32 at one end as a starting point toward the opening 150 on the side of the other end. As a result, as illustrated in FIG. 17C, the plurality of conductive layers 10 of the respective layers can be formed without voids.

Then, as the etching step (S122), the growth inhibition film 34 and the conductive film 32 left in the opening 152 are sequentially removed by etching. Here, when the growth of the W film progresses into the opening 150 in the replacement step (S120), the excess W film in the opening 150 may be simultaneously removed so as not to cause a short circuit between the plurality of conductive layers 10 on the sidewall of the opening 150. As a result, the semiconductor device having the cross section illustrated in FIG. 1 can be formed.

In addition, in the first embodiment, as illustrated in FIG. 2, on the side of the opening 152 where the conductive film 32 is disposed in the replacement step (S120), the side surface in the width direction of the conductive layer 10 to be the word line is in a substantially planar surface state, and on the side of the opening 150 to be the opened end, concavity and convexity are formed on the side surface in the width direction of the word line. Therefore, as described above, one of both side surfaces of the word line is formed so as to have a larger surface roughness than the other. Note that, even when the excess W film grown into the opening 150 is etched, concavity and convexity of the side surface on the side of the opening 150 do not completely disappear and remain, even if concavity and convexity decrease. As illustrated in FIG. 2, in the plurality of word lines arranged in the respective layers, the side surfaces 13 having the large surface roughness are formed to be adjacent to each other, and the side surfaces 11 having the small surface roughness are formed to be adjacent to each other. In other words, the plurality of word lines arranged such that arrangement positions of the side surfaces 13 having the large surface roughness and the side surfaces 11 having the small surface roughness are alternately changed are disposed in the respective layers.

Here, the conductive layer on the side of the upper layer among the plurality of stacked conductive layers 10 may be used as a selection gate on the side of the drain of the NAND string. The conductive layer 10 used as the selection gate on the side of the drain may be divided into two or more conductive layers 10 in the width direction (x direction) between the adjacent openings 150 and 152. In such a case, a division layer for dividing the conductive layer 10 into two or more regions in the width direction (x direction) is formed so as to penetrate the conductive layer 10 on the side of the upper layer used as the selection gate on the side of the drain.

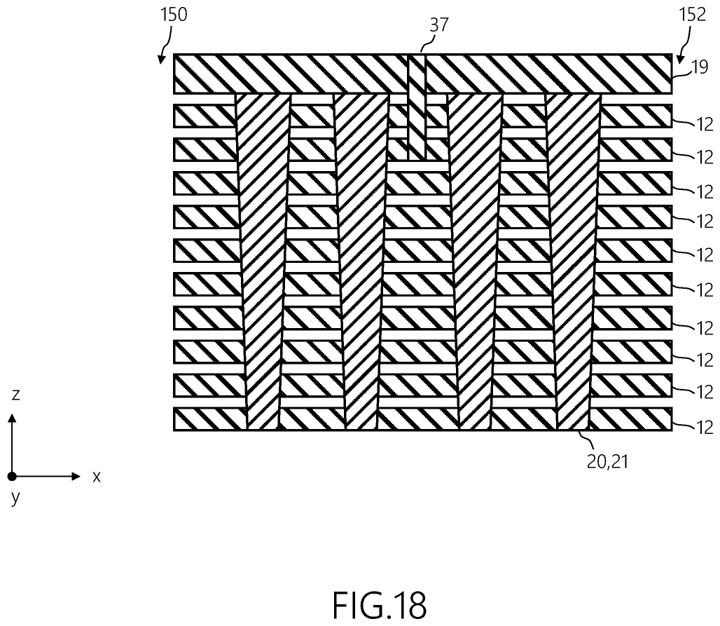

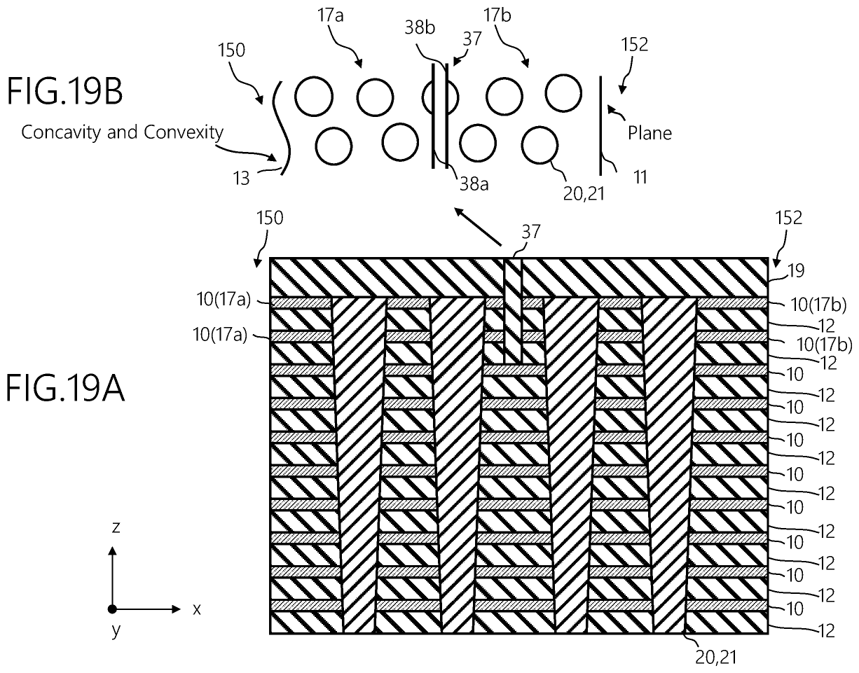

FIG. 18 is a diagram for describing an example of a cross section of a stacked film in which a division layer of a selection gate is disposed in a comparative example of the first embodiment. FIGS. 19A and 19B are diagrams for describing an example of a cross section of a stacked film in which a division layer of a selection gate is disposed in the first embodiment. FIG. 19B illustrates a top view of FIG. 19A. The scales of FIGS. 19A and 19B are not matched. In the examples of FIGS. 18 and 19A, a case where the two conductive layers 10 on the side of the upper layer are used as the selection gates is illustrated. For example, in FIGS. 18 and 19A, the four memory films 20 arranged in the x direction penetrate the respective conductive layers 10 other than the conductive layers 10 on the side of the upper layer used as the selection gates. Then, a division layer 37 divides the conductive layer 10 on the side of the upper layer into two selection gates penetrated by the two memory films 20 arranged in the x direction. For example, the division layer 37 is provided so as to overlap the center memory film 20 (and channel body 21) among the five memory films 20 arranged in the x direction as illustrated in FIG. 3, and the center memory film 20 (and channel body 21) overlapping the division layer 37 becomes a dummy NAND string and is not used as a memory cell for storing data. Alternatively, the division layer 37 is provided between the two center memory films 20 among the four memory films 20 (and channel bodies 21) arranged in the x direction as illustrated in FIG. 4 so as not to interfere with the two memory films 20 (and channel bodies 21).

The conductive layer 10 on the side of the upper layer is divided by the division layer 37, so that two conductive layers 17a and 17b arranged in the x direction are stacked on the conductive layer 10 on the side of the lower layer. At least one conductive layer 17a is formed, and has a plate-like shape penetrated in the stacking direction by a part of the plurality of channel bodies and extending in the y direction. The conductive layer 17b is disposed apart from the conductive layer 17a in the x direction. At least one conductive layer 17b is formed, and has a plate-like shape penetrated in the stacking direction by another part of the plurality of channel bodies and extending in the y direction.

In the comparative example in which the conductive material is embedded using both the openings 150 and 152 as the grooves for replacement, the division layer 37 is formed before the replacement step (S120). Then, as illustrated in FIG. 18, in the replacement step (S120), removal of the sacrificial film layer and formation of the W film are performed through the openings 150 and 152 on both sides of the division layer 37. On the other hand, in the first embodiment, a wall made of the conductive film 32 is formed on the side of the opening 152 of the openings 150 and 152. Therefore, if the division layer 37 is formed before the replacement step (S120), the region between the division layer 37 and the conductive film 32 becomes a closed region. In the closed region, it is difficult to replace the sacrificial film layer with the conductive layer 10.

Therefore, in the first embodiment, as illustrated in FIG. 19A, the division layer 37 is formed after the replacement step (S120). As a result, the conductive layer 10 between the adjacent openings 150 and 152 can be divided into two selection gates. As the material of the division layer 37, for example, SiO₂ is used.

Here, as illustrated in FIGS. 19A and 19B, one side surface 13 of both side surfaces extending in the y direction in the conductive layer 17a on the side of the upper layer has surface roughness larger than that of each of the other side surfaces 11 of the plurality of conductive layers 10 on the side of the lower layer. In addition, one side surface 13 of the conductive layer 17a on the side of the upper layer is aligned with one side surface 13 of each of the plurality of conductive layers 10 on the side of the lower layer in the stacking direction. In the conductive layer 17a, one side surface 13 of both side surfaces extending in the y direction has surface roughness larger than that of the other side surface 38a. The other side surface 38a of the conductive layer 17a is disposed to face one side surface 38b of both side surfaces extending in the y direction of the conductive layer 17b. Here, the side surface 38a and the side surface 38b are regarded as portions of the side surfaces of the conductive layer 17a and the conductive layer 17b extending in the y direction within respective regions of the conductive layer 17a and 17b not penetrated by the center memory film 20 (and channel body 21) when the division layer 37 overlaps the center memory film 20 (and channel body 21). One side surface 13 of the conductive layer 17a has surface roughness larger than those of both side surfaces 11 and 38b extending in the y direction of the conductive layer 17b. A specific description will be given below.

As illustrated in FIG. 19B, the side surface 13 on the side of one opening 150 of the selection gate divided into two parts is provided with concavity and convexity similar to those of the side surface 13 on the side of the opening 150 in the conductive layer 10 to be the word line and has the increasing surface roughness. Further, the side surface 11 on the side of the other opening 152 of the selection gate divided into two parts is in a substantially planar state, similarly to the side surface 11 on the side of the opening 152 of the conductive layer 10 to be the word line. In addition, in the selection gate divided into two parts, the surface roughness of the two side surfaces 38a and 38b facing each other with the division layer 37 therebetween depends on the condition when the groove for the division layer 37 is etched, and it is possible to perform processing so as to obtain a substantially planar processing surface in the same degree as when the opening groove to be the opening 152 is formed. Therefore, in both side surfaces of each selection gate divided into two parts, the side surface 13 on the side of the opening 150 of one selection gate described above is formed to have the larger surface roughness than the other three side surfaces in a substantially planar state.

Note that the number of stacked layers of the selection gates is not limited to two, and at least one selection gate may be disposed on the side of the upper layer of the plurality of conductive layers 10. In addition, the number of division layers 37 disposed between the pair of openings 150 and 152 can also be freely set.

As described above, according to the first embodiment, it is possible to reduce or avoid the voids generated in the conductive layers to be the word lines of the three-dimensional NAND type flash memory device.

The embodiments have been described above with reference to the specific examples. However, the present disclosure is not limited to these specific examples.

Further, the thickness of each film, and the size, the shape, and the number of openings can be appropriately selected and used as desired for semiconductor integrated circuits and various semiconductor elements.

Further, all semiconductor devices including the elements of the present disclosure and capable of being appropriately designed and changed by those skilled in the art and methods for fabricating the semiconductor devices are included in the scope of the present disclosure.

For simplicity of explanation, methods commonly used in the semiconductor industry, for example, photolithography processes, cleaning before and after processes, and the like are omitted. However, it is needless to say that these methods can be included.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods and devices described herein may be made without departing from the spirit of the inventions. The accompanying claims and their equivalents are intended to cover such forms or modifications as would fall within the scope and spirit of the inventions.

What is claimed is:

1. A semiconductor device comprising:
a plurality of first conductive layers stacked apart from each other and including a plate-like shape extending in a first direction intersecting a stacking direction of the plurality of first conductive layers, one of both side surfaces of the plurality of first conductive layers extending in the first direction having larger surface roughness than the other of both side surfaces;
a plurality of channel bodies configured to penetrate the plurality of first conductive layers in the stacking direction, the plurality of channel bodies including semiconductors; and
a memory film extending in the stacking direction between each of the plurality of channel bodies and the plurality of first conductive layers and including a charge accumulation film.

2. The device according to claim 1, wherein
the plurality of first conductive layers are formed without voids.

3. The device according to claim 1, further comprising:
a plurality of dielectric layers alternately stacked with the plurality of first conductive layers and disposed to be in direct contact with adjacent first conductive layers.

4. The device according to claim 1, wherein
the memory film further includes a block dielectric film extending in the stacking direction between the charge accumulation film and the plurality of first conductive layers.

5. The device according to claim 1, wherein
the plurality of channel bodies are disposed in a staggered lattice, and
the one of both side surfaces of the plurality of first conductive layers repeats concavity and convexity in a period that is twice an arrangement pitch along the first direction of the plurality of channel bodies.

6. The device according to claim 1, wherein
the plurality of channel bodies are disposed in a square lattice, and
the one of both side surfaces of the plurality of first conductive layers repeats concavity and convexity in a period of an arrangement pitch along the first direction of the plurality of channel bodies.

7. The device according to claim 1, further comprising:
a plurality of second conductive layers disposed side by side with the plurality of first conductive layers in a second direction intersecting the stacking direction and the first direction, the plurality of second conductive layers being stacked apart from each other and including a plate-like shape extending in the first direction, one of both side surfaces of the plurality of second conductive layers extending in the first direction having larger surface roughness than the other of both side surfaces, wherein
the plurality of first conductive layers and the plurality of second conductive layers are adjacent to each other in the second direction such that respective ones of the both side surfaces having larger surface roughness face each other while being insulated from each other.

8. The device according to claim 1, further comprising:
at least one third conductive layer stacked above the plurality of first conductive layers, the third conductive layer being penetrated in the stacking direction by a part of the plurality of channel bodies and including a plate-like shape extending in the first direction; and
at least one fourth conductive layer stacked above the plurality of first conductive layers so as to be separated from the third conductive layer in a second direction intersecting the stacking direction and the first direction, the fourth conductive layer being penetrated in the stacking direction by another part of the plurality of channel bodies and including a plate-like shape extending in the first direction, wherein
one of both side surface portions of the third conductive layer has larger surface roughness than the other of both side surfaces of the plurality of first conductive layers, the both side surface portions extending in the first direction within regions of the third conductive layer not penetrated by the plurality of channel bodies.

9. The device according to claim 8, wherein
the one of both side surface portions of the third conductive layer is aligned with the one of both side surfaces of the plurality of first conductive layers in the stacking direction.

10. The device according to claim 1, further comprising:
at least one third conductive layer stacked above the plurality of first conductive layers, the third conductive layer being penetrated in the stacking direction by a part of the plurality of channel bodies and including a plate-like shape extending in the first direction; and
at least one fourth conductive layer stacked above the plurality of first conductive layers so as to be separated from the third conductive layer in a second direction intersecting the stacking direction and the first direction, the fourth conductive layer being penetrated in the stacking direction by another part of the plurality of channel bodies and including a plate-like shape extending in the first direction, wherein
one of both side surface portions of the third conductive layer has larger surface roughness than the other of both side surface portions, the both side surface portions extending in the first direction within regions of the third conductive layer not penetrated by the plurality of channel bodies.

11. The device according to claim 10, wherein
the one of both side surface portions of the third conductive layer is aligned with the one of both side surfaces of the plurality of first conductive layers in the stacking direction.

12. The device according to claim 10, wherein
the other of both side surface portions of the third conductive layer is disposed to face one of both side surface portions of the fourth conductive layer extending in the first direction within regions of the fourth conductive layer not penetrated by the plurality of channel bodies.

13. The device according to claim 10, wherein
the one of both side surface portions of the third conductive layer has larger surface roughness than both side surface portions of the fourth conductive layer extending in the first direction within regions of the fourth conductive layer not penetrated by the plurality of channel bodies.

14. The device according to claim 3, wherein
tungsten is used as a material of the plurality of first conductive layers, and
silicon oxide is used as the plurality of dielectric layers.

15. The device according to claim 4, wherein
aluminum oxide is used as a material of the block dielectric film.

16. A method for fabricating a semiconductor device, comprising:
forming a stacked film by alternately stacking a sacrificial film layer and a dielectric layer above a substrate;
forming a plurality of openings separating the stacked film;
forming a conductive film on each of side surfaces of the plurality of openings;
removing the conductive film formed in every other opening among the plurality of openings;
removing the sacrificial film layer of the stacked film through the opening from which the conductive film has been removed; and
growing a conductive material toward a side of the opening from which the conductive film has been removed with the conductive film left without being removed as a starting point, in a space generated by removing the sacrificial film layer.

17. The method according to claim 16, further comprising:
forming a growth inhibition film inhibiting a growth of the conductive material in the opening inside the conductive film formed on the side surfaces of the plurality of openings.

18. The method according to claim 17, wherein
the growth inhibition film is formed so as not to completely embed the plurality of openings.

19. The method according to claim 16, further comprising:
removing the conductive film left in the opening after growing the conductive material in the space.

20. The method according to claim 16, further comprising:
forming a division layer dividing a conductive layer made of the conductive material formed locally on an upper layer side of the stacked film between the plurality of openings, after growing the conductive material in the space.
